(19) United States
(12) Patent Application Publication
(10) Pub. No.: US 2022/0252394 A1
(43) Pub. Date: Aug. 11, 2022

(54) Device and Method for Determining a Surface State of a Roadway Traveled or to be Traveled by a Vehicle

(71) Applicant: Robert Bosch GmbH, Stuttgart (DE)

(72) Inventors: Wolfgang Welsch, Heidelberg (DE); Sina Fella, Neuenstadt (DE); Andreas Baumgartner, Auenstein (DE); Stefan Kuntz, Flein (DE)

(21) Appl. No.: 17/619,286

(22) PCT Filed: Jun. 3, 2020
(86) PCT No.: PCT/EP2020/065310

§ 371 Date: Dec. 15, 2021

(30) Foreign Application Priority Data
Jun. 19, 2019 (DE) 10 2019 208 881.3

(51) Int. Cl. G01B 11/30; G01N 21/47; H01L 25/16

(52) U.S. Cl. CPC G01B 11/303; G01N 2201/0216; H01L 25/167; G01N 21/47

(57) ABSTRACT

A device for determining a surface state of a roadway traveled or to be traveled by a vehicle, wherein the device comprises at least one light source for emitting primary light in the direction of the roadway traveled or to be traveled; at least one detector device for detecting secondary light that has been reflected and/or scattered by the roadway traveled or to be traveled; and an evaluation unit configured to emit, on the basis of the secondary light detected, the surface state of the roadway traveled or to be traveled by the vehicle. The essence of the invention is that the device furthermore comprises at least one first semiconductor chip, wherein at least two diodes are arranged on the at least one first semiconductor chip.

The present invention relates to a device for determining a surface state of a roadway traveled or to be traveled by a vehicle and to a corresponding method.

### PRIOR ART

DE 10 2011 081 362 A1 discloses a method and a device for determining a surface state of a roadway traveled or to be traveled by a vehicle. The device has an interface for reading in a reflection signal which represents a light intensity or a light color that is reflected from a position in the surroundings of the vehicle, wherein the position is irradiated by at least one headlight of the vehicle; a unit for comparing the reflection signal to a value, which is read out from a memory, or a comparison signal, wherein the value represents a predetermined light intensity and/or a predetermined light color and/or the comparison signal represents a light intensity and/or a light color at a comparison position adjacent to the position; and an interface for outputting a surface state signal which represents the surface state of the roadway traveled and/or to be traveled by the vehicle if the reflection signal is in a predetermined relationship to the value read out from the memory or to the comparison signal.

### SUMMARY OF THE INVENTION

The present invention s directed to a device for determining a surface state of a roadway traveled or to be traveled by a vehicle. The device has at least one light source for emitting primary light in the direction of the roadway traveled or to be traveled; at least one detector device for detecting secondary light which was reflected and/or scattered on the roadway traveled or to be traveled; and an evaluation unit, which is designed to determine, on the basis of the detected secondary light, the surface state of the roadway traveled or to be traveled by the vehicle.

According to the invention, the device furthermore has at least one first semiconductor chip, wherein at least two diodes are arranged on the at least one first semiconductor chip.

A device can be understood in the present case as an electrical device which processes sensor signals and outputs control signals as a function thereof. The device can have an interface, which can be designed in hardware and/or software. In a hardware design, the interfaces can be, for example, part of a so-called system ASIC, which contains greatly varying functions of the device. However, it is also possible that the interfaces are separate integrated circuits or at least partially consist of discrete components. In a software design, the interfaces can be software modules which are provided, for example, on a microcontroller in addition to other software modules.

A roadway traveled or to be traveled by a vehicle is to be understood as a roadway or road on which the vehicle has already covered a route or will cover a route in the immediate future. A surface state is to be understood as a physical property of the surface of the roadway which is relevant for the driving dynamics of the vehicle on the roadway. For example, the surface state can be represented by moisture, wetness, icing of the roadway, covering of the roadway with snow, grit, leaves, oil, or the like, so that the vehicle has changed movement dynamics in relation to a dry roadway when it drives over the roadway having this surface state. A surface state can be understood as a coefficient of friction of the roadway traveled or to be traveled.

The device can be understood as an optical sensor. The device can be understood as a road state sensor. The light source can be designed as a laser device. The light source can be designed as an LED light source (“light-emitting diode”). The light source can, for example, emit primary light in the near infrared wavelength range (approximately 800 nm to 3000 nm). The light source can have at least one emitting diode. The light source can have multiple emitting diodes, wherein the multiple emitting diodes can be designed to emit primary light of various wavelengths and/or various polarizations. An emitting diode can be designed as a laser diode. An emitting diode can be designed as a light-emitting diode (LED). The detector device can have at least one photodiode. The detector device can be designed to detect secondary light of various wavelength) and/or various polarizations. The detector device can furthermore have at least one wavelength filter. In particular if the detector device has at least two photodiodes, at least one wavelength filter can be designed to distribute secondary light of various wavelengths onto the at least two photodiodes.

The advantage of the invention is that technically or financially complex optical geometries can be avoided. The angles between the light source or the emitting diodes, the roadway, and the detector device or the photodiodes can be adjusted for various wavelengths. It is possible to implement nearly the identical angle of incidence for emitting diodes of various wavelengths. It is possible to avoid the device having to have multiple optical lenses. It is possible to avoid the device having to have multiple optical windows. Preferably, only a single optical lens and/or a single optical window is necessary. The optical alignment, thus that all components point at the same point on the roadway, is thus simplified. The device can be cost-effective in this way. In addition, risks, for example, signal interference due to soiling of the windows can be reduced. Additional fibers or other optical elements to conduct primary light and/or secondary light from/to the light source/the detector device can be avoided. The installation space of the device can be minimized, which is very important in particular upon use of the device in the field of highly automated driving. Furthermore, a joint temperature stabilization of the at least two diodes is possible. A joint temperature stabilization element can be sufficient for this purpose.

In one advantageous embodiment of the invention, it is provided that the at least two diodes on the at least one first semiconductor chip are designed as at least one emitting diode of the light source and as at least one photodiode of the detector device. In other words: the at least one emitting diode and the at least one photodiode are arranged jointly on the first semiconductor chip. The number of the emitting diodes can in particular be equal to the number of the photodiodes. The advantage of this embodiment is that the spacing of the light source and the detector device can be reduced. In this way, nearly equal angles of incidence and detection can be implemented. The signal quality which can be achieved during use of the device can be significantly improved. A common optical unit (for example in the form of optical lenses) can be sufficient for the light source and the detector device. The space requirement can be reduced by the common arrangement of the light source and the detector device on the first semiconductor chip. The installation space of the device can be minimized even more strongly. With an equal number of emitting diodes and photodiodes, the advantage additionally results that the photodiodes can be designed in such a way that they are only sensitive for a respective emitting diode wavelength. The useful signal can be increased in comparison to interfering influences (for example external light sources) in this way. If precisely one emitting diode and one photodiode are arranged on the first semiconductor chip, costs can be saved. In a further advantageous embodiment of the invention, it is provided that a number of emitting diodes of the light source is greater than a number of photodiodes of the detector device. The advantage of this embodiment is that costs for the photodiodes can be reduced.

In a further advantageous embodiment of the invention, it is provided that a number of photodiodes of the detector device is greater than a number of emitting diodes of the light source. The advantage of this embodiment is that specifically wavelength-sensitive photodiodes can be used. By means of such photodiodes, signals of the individual emitted wavelengths or wavelength ranges can be separated again. The useful signal can be increased in comparison to interfering influences (for example external light sources) in this way.

In one advantageous embodiment of the invention, it is provided that the device furthermore has at least one second semiconductor chip, and wherein at least one diode is arranged on the at least one second semiconductor chip. For example, the light source can be arranged on the first semiconductor chip and the detector device can be arranged on the second semiconductor chip, or vice versa. The advantage of this embodiment is that a higher level of flexibility is enabled in the arrangement of the light source and the detector device. Thus, for example, various geometries are possible and the alignment of the entry or exit angles of light source and detector device are possible by way of suitable devices. Due to the separate arrangement of the detector device from the light source, interfering influences due to, for example, adjacent electronic components (for example caused by the electrical currents through the light source or driver components) can be reduced.

In a further advantageous embodiment of the invention, it is provided that the at least two diodes on the at least one first semiconductor chip are designed as at least two emitting diodes of the light source and the at least one diode on the at least one second semiconductor chip is designed as at least one photodiode of the detector device. A number of emitting diodes on the first semiconductor chip can be greater than, equal to, or also less than a number of photodiodes on the second semiconductor chip here. The number of emitting diodes on the first semiconductor chip is preferably equal to or greater than the number of photodiodes on the second semiconductor chip. The advantage when the number of the emitting diodes on the first semiconductor chip is greater than the number of the photodiodes on the second semiconductor chip is that costs for the photodiodes can be reduced. The advantage when the number of the emitting diodes on the first semiconductor chip is equal to the number of the photodiodes on the second semiconductor chip is that the photodiodes can be designed in such a way that they are only sensitive for a respective emitting diode wavelength. The useful signal can be increased in comparison to interfering influences (for example external light sources) in this way. The advantage when the number of the emitting diodes on the first semiconductor chip is less than the number of the photodiodes on the second semiconductor chip is that specifically wavelength-sensitive photodiodes can be used. By means of such photodiodes, signals of the individual emitted wavelengths or wavelength ranges can be separated again. The useful signal can be increased in comparison to interfering influences (for example external light sources) in this way. In a further advantageous embodiment of the invention, it is provided that the at least two diodes on the at least one first semiconductor chip are designed as at least two photodiodes of the detector device and the at least one diode on the at least one second semiconductor chip is designed as at least one emitting diode of the light source. A number of photodiodes on the first semiconductor chip can be greater than, equal to, or also less than a number of emitting diodes on the second semiconductor chip here. The number of photodiodes on the first semiconductor chip is preferably equal to or greater than the number of emitting diodes on the second semiconductor chip. The advantage when the number of the photodiodes on the first semiconductor chip is greater than the number of the emitting diodes on the second semiconductor chip is that specifically wavelength-sensitive photodiodes can be used. By means of such photodiodes, signals of the individual emitted wavelengths or wavelength ranges can be separated again. The useful signal can be increased in comparison to interfering influences (for example external light sources) in this way. The advantage when the number of the photodiodes on the first semiconductor chip is equal to the number of the emitting diodes on the second semiconductor chip is that the photodiodes can be designed in such a way that they are only sensitive for a respective emitting diode wavelength. The useful signal can be increased in comparison to interfering influences (for example external light sources) in this way. The advantage when the number of the photodiodes on the first semiconductor chip is less than the number of the emitting diodes on the second semiconductor chip is that costs for the photodiodes can be reduced.

In a further advantageous embodiment of the invention, it is provided that the device furthermore has at least one first temperature stabilization element, wherein the first temperature stabilization element is arranged on the at least one first semiconductor chip. If the device also has at least one second semiconductor chip, it is preferably furthermore provided that the device furthermore has at least one second temperature stabilization element, wherein the second temperature stabilization element is arranged on the at least one second semiconductor chip. The temperature stabilization element can be designed as a Peltier element. The temperature stabilization element can be designed for the purpose of stabilizing the temperature by means of water and/or air cooling.

A first and/or second semiconductor chip can be produced by growing the structures arranged on the semiconductor chip on a wafer for the semiconductor chip. A first and/or second semiconductor chip can be produced by growing, which can be carried out separately from one another, of the structures arranged on the semiconductor chip on at least two wafers for the semiconductor chip and subsequently bringing together the at least two wafers to form a first and/or second semiconductor chip.

The invention is furthermore directed to a method for determining a surface state of a roadway traveled or to be traveled by a vehicle by means of an above-described device. The method has the steps of emitting primary light in the direction of the roadway traveled or to be traveled by means of at least one light source; detecting secondary light which was reflected and/or scattered by the roadway traveled or to be traveled by means of at least one detector device; and determining the surface state of the roadway traveled or to be traveled by the vehicle on the basis of the detected secondary light by means of an evaluation unit. In this case, the device has at least one first semiconductor chip, wherein at least two diodes are arranged on the at least one first semiconductor chip.

### DRAWINGS

Exemplary embodiments of the present invention are explained in more detail hereinafter on the basis of the appended drawings. Identical reference signs in the figures identify identical or identically acting elements, in which:

FIG. 1 shows an exemplary embodiment of a device for determining a surface state of a roadway traveled or to be traveled by a vehicle having a first semiconductor chip and a second semiconductor chip;

FIG. 2 shows an exemplary embodiment of a first semiconductor chip;

FIG. 3 shows an exemplary embodiment of a first semiconductor chip and a second semiconductor chip;

FIG. 4 shows a further exemplary embodiment of a first semiconductor chip;

FIG. 5 shows a further exemplary embodiment of a first semiconductor chip and a second semiconductor chip;

FIG. 6 shows a further exemplary embodiment of a first semiconductor chip;

FIG. 7 shows a further exemplary embodiment of a first semiconductor chip.

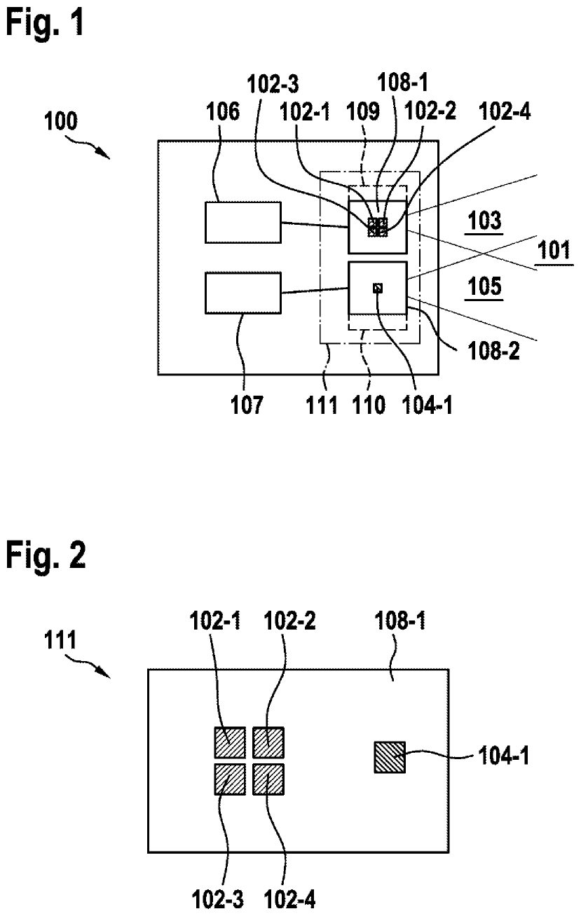

FIG. 1 shows an exemplary embodiment of a device 100 for determining a surface state of a roadway 101 traveled or to be traveled by a vehicle having a first semiconductor chip 108-1 and a second semiconductor chip 108-2. The device 100 has the light source 102 for emitting primary light 103 in the direction of the roadway 101 traveled or to be traveled. The light source 102 can be activatable by means of the activation unit 106. The device 100 furthermore has the detector device 104 for detecting secondary light 105, which has been reflected and/or scattered by the roadway 101 traveled or to be traveled. Furthermore, the device 100 has the evaluation unit 107, which is designed to determine, on the basis of the detected secondary light 105, the surface state of the roadway 101 traveled or to be traveled by the vehicle. The device 100 has the first semiconductor chip 108-1. The four diodes 102-1 to 102-4 are arranged on the first semiconductor chip 108-1. The four diodes 102-1 to 102-4 are designed as four emitting diodes of the light source 102. The device 100 furthermore has the second semiconductor chip 108-2. A diode 104-1 is arranged on the second semiconductor chip 108-2. The diode 104-1 is designed as a photodiode 104-1 of the detector device 104. The number of the emitting diodes 102-1 to 102-4 on the first semiconductor chip 108-1 is thus greater than the number of the photodiodes 104-1 on the second semiconductor chip 108-2. The device 100 furthermore has a first temperature stabilization element 109 in the example. The temperature stabilization element 109 is shown by dashed lines, since it can optionally be provided. The first temperature stabilization element 109 is arranged on the first semiconductor chip 108-1. The device 100 furthermore has a second temperature stabilization element 110 in the example. The temperature stabilization element 110 is shown by dashed lines, since it can optionally be provided. The second temperature stabilization element 110 is arranged on the second semiconductor chip 108-2.

FIGS. 2-7 show further exemplary embodiments of the region 111 of the device 100 shown in FIG. 1. The optionally provided temperature stabilization elements were not shown here for the sake of simplicity.

FIG. 2 shows an exemplary embodiment of a first semiconductor chip 108-1. The at least two diodes on the first semiconductor chip 108-1 are designed as four emitting diodes 102-1 to 102-4 and as one photodiode 104-1. The emitting diodes 102-1 to 102-4 and the photodiode 104-1 are thus arranged jointly on the first semiconductor chip 108-1. The number of the emitting diodes of the light source 102 is greater here than the number of the photodiodes of the detector device 104 on the first semiconductor chip 108-1.

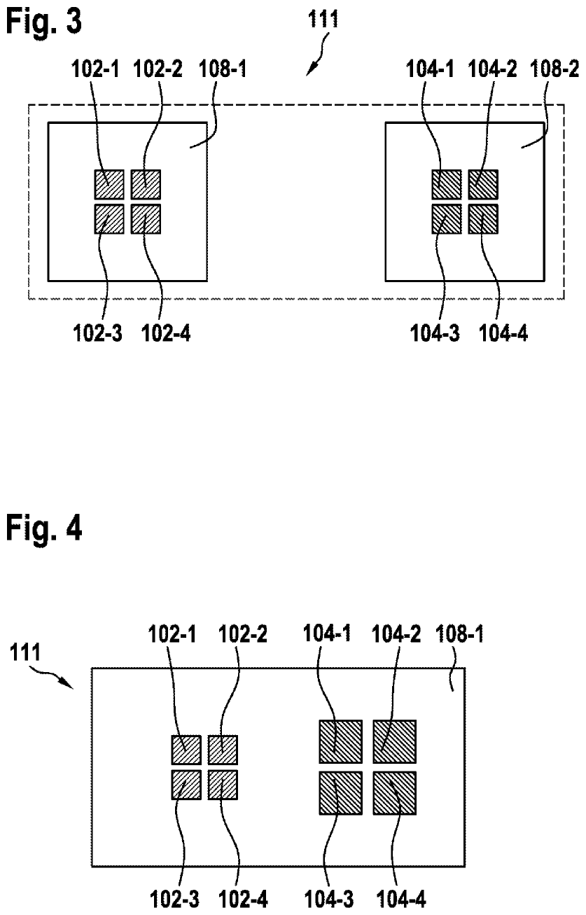

FIG. 3 shows an exemplary embodiment of a first semiconductor chip 108-1 and a second semiconductor chip 108-2. The at least two diodes on the first semiconductor chip 108-1 are designed as four emitting diodes 102-1 to 102-4. The four photodiodes 104-1 to 104-4 are arranged on the second semiconductor chip 108-2. The number of the emitting diodes 102-1 to 102-4 on the first semiconductor chip 108-1 is thus equal to the number of the photodiodes 104-1 to 104-4 on the second semiconductor chip 108-2.

Therefore, the light source 102 is arranged on the first semiconductor chip 108-1 and the detector device 104 is arranged on the second semiconductor chip 108-2. The light source 102 and the detector device 104 are arranged separately from one another. The detector device 104 can furthermore have at least one wavelength filter (not shown here) for distributing secondary light of various wavelengths onto the photodiodes 104-1 to 104-4.

FIG. 4 shows a further exemplary embodiment of a first semiconductor chip 108-1. The at least two diodes on the first semiconductor chip 108-1 are designed as four emitting diodes 102-1 to 102-4 and as four photodiodes 104-1 to 104-4. The emitting diodes 102-1 to 102-4 and the photodiodes 104-1 to 104-4 are thus arranged jointly on the first semiconductor chip 108-1, The number of the emitting diodes of the laser device 102 is equal to the number of the photodiodes of the detector device 104 on the first semiconductor chip 108-1 in this case. The detector device 104 can furthermore have at least one wavelength filter (not shown here) for distributing secondary light of various wavelengths onto the photodiodes 104-1 to 104-4.

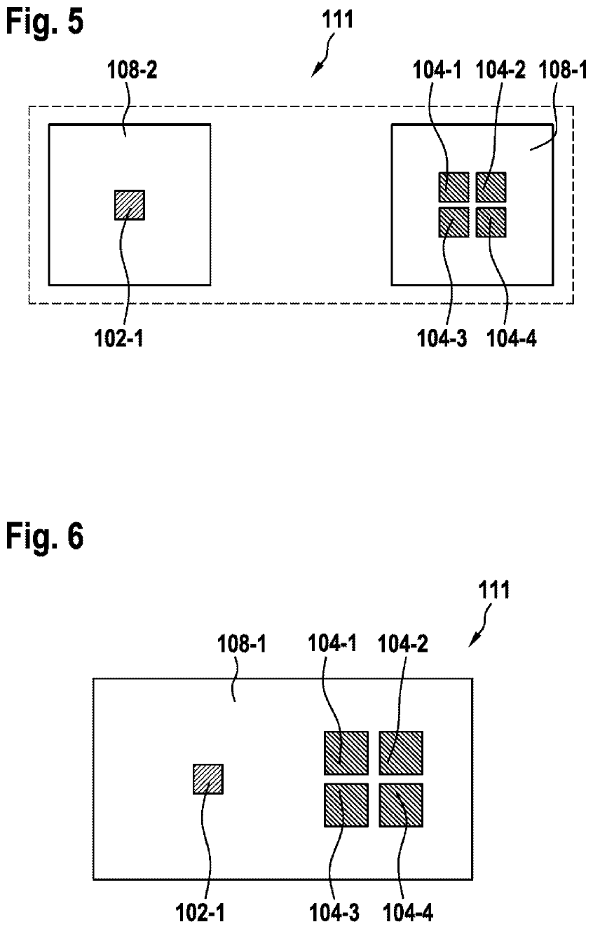

FIG. 5 shows a further exemplary embodiment of a first semiconductor chip 108-1 and a second semiconductor chip 108-2. The at least two diodes on the first semiconductor chip 108-1 are designed as four photodiodes 104-1 to 104-4. One emitting diode 102-1 is arranged on the second semiconductor chip 108-2. The number of the photodiodes 104-1 to 104-4 on the first semiconductor chip 108-1 is thus greater than the number of the emitting diodes on the second semiconductor chip 108-2. The detector device 104 is thus arranged on the first semiconductor chip 108-1 and the light source 102 is arranged on the second semiconductor chip 108-2. The light source 102 and the detector device 104 are arranged separately from one another. The detector device 104 can furthermore have at least one wavelength filter (not shown here) for distributing secondary light of various wavelengths onto the photodiodes 104-1 to 104-4.

FIG. 6 shows a further exemplary embodiment of a first semiconductor chip 108-1. The at least two diodes on the first semiconductor chip 108-1 are designed as four photodiodes 104-1 to 104-4 and as one emitting diode 102-1. The photodiodes 104-1 to 104-4 and the emitting diode 102-1 are thus jointly arranged on the first semiconductor chip 108-1, The number of the photodiodes of the detector device 104 is greater here than the number of the emitting diodes of the laser device 102 on the first semiconductor chip 108-1, The detector device 104 can furthermore have at least one wavelength filter (not shown here) for distributing secondary light of various wavelengths onto the photodiodes 104-1 to 104-4.

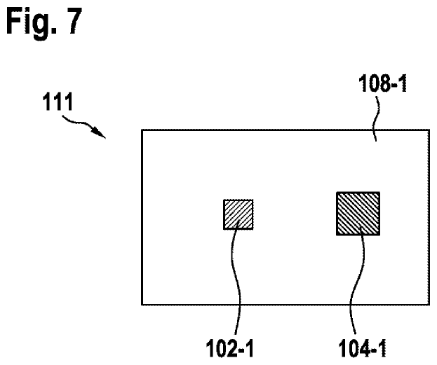

FIG. 7 shows a further exemplary embodiment of a first semiconductor chip and a second semiconductor chip 108-1. The at least two diodes on the first semiconductor chip 108-1 are designed as one emitting diode 102-1 and as one photodiode 104-1. The emitting diode 102-1 and the photodiode 104-1 are thus arranged jointly on the first semiconductor chip 108-1. The number of the emitting diodes of the light source 102 is equal here to the number of the photodiodes of the detector device 104 on the first semiconductor chip 108-1.

1. A device for determining a surface state of a roadway, which is one of traveled and to be traveled by a vehicle, the device comprising:
at least one light source configured to emit primary light in a direction of the roadway;
at least one detector configured to detect secondary light that has been one of reflected and scattered from the roadway;
an evaluation device configured to determine, based on the detected secondary light, the surface state of the roadway; and
at least one first semiconductor chip having at least two diodes arranged thereon.

2. The device as claimed in claim 1, wherein the at least two diodes arranged on the at least one first semiconductor chip include (i) at least one emitting diode of the at least one light source and (ii) at least one photodiode of the at least one detector.

3. The device as claimed in claim 2, wherein a number of emitting diodes of the at least one light source is greater than a number of photodiodes of the at least one detector.

4. The device as claimed in claim 2, wherein a number of photodiodes of the at least one detector is greater than a number of emitting diodes of the at least one light source.

5. The device as claimed in claim 1 further comprising:
at least one second semiconductor chip having at least one diode arranged thereon.

6. The device as claimed in claim 5, wherein the at least two diodes arranged on the at least one first semiconductor chip include at least two emitting diodes of the at least one light source and the at least one diode arranged on the at least one second semiconductor chip include at least one photodiode of the at least one detector.

7. The device as claimed in claim 6, wherein the at least two diodes arranged on the at least one first semiconductor chip include as at least two photodiodes of the at least one detector and the at least one diode arranged on the at least one second semiconductor chip include at least one emitting diode of the at least one light source.

8. The device as claimed in claim 1 further comprising:
at least one first temperature stabilization element arranged on the at least one first semiconductor chip.

9. A method for determining a surface state of a roadway, which is one of traveled and to be traveled by a vehicle, the method comprising:
emitting, using at least one light source of a device, primary light in a direction of the roadway;
detecting, using at least one detector of the device, secondary light that has been one of reflected and scattered from the roadway; and
determining, using an evaluation device of the device, the surface state of the roadway based on the detected secondary light,
wherein the device has at least one first semiconductor chip having at least two diodes arranged thereon.
